(19) United States
(12) Patent Application Publication
(10) Pub. No.: US 2025/0351631 A1
(43) Pub. Date: Nov. 13, 2025

(54) EPITAXIAL DIE AND CHIP DIE FOR SEMICONDUCTOR LIGHT-EMITTING DEVICE, AND MANUFACTURING METHOD THEREOF

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,657

(22) PCT Filed: Nov. 29, 2023
(86) PCT No.: PCT/KR2023/019492

§ 371 Date: Oct. 27, 2024

(30) Foreign Application Priority Data
Nov. 29, 2022 (KR) 10-2022-0163166

(51) Int. Cl. H10H 20/857; H10H 20/01; H10H 20/83; H10H 20/85

(52) U.S. Cl. CPC H10H 20/857; H10H 20/018; H10H 20/021; H10H 20/83; H10H 20/8508

(57) ABSTRACT

The present invention relates to an epitaxial die and a chip die for a semiconductor light-emitting device, and a manufacturing method thereof, wherein only one of two electrodes is exposed to the outside, and a process of forming a positive ohmic contact electrode (p-ohmic contact electrode) or a negative ohmic contact electrode (n-ohmic contact electrode) is completed in an epitaxial die manufacturing step so as to achieve dramatic thickness reduction and easy reduction of the chip die size, thereby improving the light output.

### TECHNICAL FIELD

The present invention relates to an epitaxial die and a chip die for a semiconductor light-emitting device, and a method of manufacturing the same, and more particularly, to an epitaxial die and a chip die for a semiconductor light-emitting device, in which only one of two electrodes is exposed to the outside, and a process of forming a p-ohmic contact electrode or an n-ohmic contact electrode is completed at the operation of manufacturing the epitaxial die, thereby enabling a significant reduction in thickness and facilitating a reduction in chip die size to improve light output, and a method of manufacturing the same.

### BACKGROUND ART

In general, micro light-emitting diode (LED) displays (including mini LED displays) can be classified into micro LED displays with a passive matrix (PM) driving method and micro LED displays with an active matrix (AM) driving method.

Here, PM-driven micro LED displays typically have a sapphire support substrate, which finally remains, and use sorted thick BGR (Blue, Green, and Red) chips (with both fully fabricated positive and negative electrodes of the LED), which are transferred using a chip die-level process in which either horizontal chips or flip chips can be generally utilized.

In addition, AM-driven micro LED displays typically do not have a sapphire support substrate, which finally remains, and use unsorted thin BGR (Blue, Green, and Red) chips (with both fully fabricated positive and negative electrodes of the LED), which are transferred using a wafer-level process in which all horizontal chips, flip chips, and vertical chips can be generally utilized.

These conventional typical PM-and AM-driven micro LED displays have the following common issues.

First, when considering the application of vertical chips to reduce chip die size, there is a problem that, unlike flip chips, which allow defects to be immediately confirmed after bonding, in the case of vertical chips, defects can be confirmed after bonding and subsequent top-level wiring.

Further, in terms of a bonding process, higher precision is required in the bonding process due to the reduction in chip die size, and improved bonding strength is required due to the reduction in bonding area.

Further, in terms of a tiling process in which a plurality of unit displays are combined like tiles, there is an issue in which boundaries become distinct when the displays are turned off or show a black screen, and this is more noticeable in the PM driving method compared to the AM driving method. In addition, although many aspects have been improved, there is still an issue in which boundaries are visible on monochromatic screens and still images, and when tiling based on thin-film transistor (TFT) glass panels, the process is challenging due to the risk of glass breakage. Furthermore, due to the tolerance relationship between pixel pitch and tiling boundaries, various issues exist, including the expectation that the tiling process will be difficult to apply to products smaller than 100 inches.

Meanwhile, in the conventional PM-driven micro LED displays, the reduction in chip die size is the greatest challenge. That is, from an aspect ratio perspective, achieving a reduction in chip die size essentially requires decreasing a thickness of a final support substrate made of sapphire, but the current limit for the thickness of the sapphire support substrate is about 80 μm to 70 μm, and when reducing the thickness below 50 μm, a substrate breaking issue occurs. Further, there are complex issues related to chip measurement and classification in this type of micro LED display, and it is expected that flip chips will be mainly used in this type of display rather than horizontal and vertical chips, but when the flip chips are used, high-precision and high-speed bonding processes, as well as materials for them, are separately required.

Further, in conventional AM-driven micro LED displays, in which the final support substrate is not present and chip die size reduction is possible, there are issues related to resolving defects (No Good, NG). That is, the fundamental issues in epitaxial and fab processes, such as yield improvement related to wavelength and electrical characteristics at the chip-on-wafer (COW) level, have not been resolved, and there is difficulty in 100% sorting and removal of defective (NG) chips. In order to address these issues, approaches such as redundancy have been recently attempted, but have not provided a fundamental solution.

### DISCLOSURE

### Technical Problem

The present invention is directed to solving the above-mentioned conventional problems and providing an epitaxial die and a chip die for a semiconductor light-emitting device, in which only one of two electrodes is exposed to the outside, and a process of forming a p-ohmic contact electrode or an n-ohmic contact electrode is completed at the operation of manufacturing the epitaxial die, thereby enabling a significant reduction in thickness and facilitating a reduction in chip die size to improve light output, a semiconductor light-emitting device including the same, and a method of manufacturing the same.

### Technical Solution

According to the present invention, the above object is achieved by an epitaxial die for a semiconductor light-emitting device, including a support substrate, a bonding layer formed on the support substrate, an epitaxial protection layer formed on the bonding layer, a first ohmic electrode formed on the epitaxial protection layer, and a light-emitting part formed on the first ohmic electrode and configured to generate light, wherein the light-emitting part includes a first semiconductor region having a first conductivity type, an active region formed on the first semiconductor region and configured to generate light using recombination of electrons and holes, and a second semiconductor region formed on the active region and having a second conductivity type.

According to the present invention, the above object is achieved by an epitaxial die for a semiconductor light-emitting device, including a support substrate, a bonding layer formed on the support substrate, a first ohmic electrode formed on the bonding layer, and a light-emitting part formed on the first ohmic electrode and configured to generate light, wherein the light-emitting part includes a second semiconductor region having a second conductivity type, an active region formed on the second semiconductor region and configured to generate light using recombination of electrons and holes, and a first semiconductor region formed on the active region and having a first conductivity type.

According to the present invention, the above object is achieved by a method of manufacturing an epitaxial die for a semiconductor light-emitting device, including a light-emitting part forming operation of forming a light-emitting part, which generates light, on a growth substrate, a first electrode forming operation of forming a first ohmic electrode on the light-emitting part, a protection layer forming operation of forming an epitaxial protection layer on the first ohmic electrode, a bonding operation of bonding a support substrate and the epitaxial protection layer through a bonding layer, and a removal operation of removing the growth substrate, wherein the light-emitting part includes a first semiconductor region having a first conductivity type, an active region formed on the first semiconductor region and configured to generate light using recombination of electrons and holes, and a second semiconductor region formed on the active region and having a second conductivity type.

According to the present invention, the above object is achieved by a method of manufacturing an epitaxial die for a semiconductor light-emitting device, including a light-emitting part forming operation of forming a light-emitting part, which generates light, on a growth substrate, a protection layer forming operation of forming an epitaxial protection layer on the light-emitting part, an adhesion operation of bonding a temporary substrate and the epitaxial protection layer through an adhesive layer, a first removal operation of removing the growth substrate, a first electrode forming operation of forming a first ohmic electrode on a surface of the light-emitting part from which the growth substrate is removed, a bonding operation of bonding a support substrate and the first ohmic electrode through a bonding layer, and a second removal operation of removing the temporary substrate, and etching and removing the adhesive layer and the epitaxial protection layer, wherein the light-emitting part includes a second semiconductor region having a second conductivity type, an active region formed on the second semiconductor region and configured to generate light using recombination of electrons and holes, and a first semiconductor region formed on the active region and having a first conductivity type.

According to the present invention, the above object is achieved by a chip die for a semiconductor light-emitting device, including a support substrate, a bonding layer formed on the support substrate, an epitaxial protection layer formed on the bonding layer, a first ohmic electrode formed on the epitaxial protection layer, a light-emitting part formed on the first ohmic electrode and configured to generate light, and a second ohmic electrode formed on the light-emitting part, wherein the light-emitting part includes a first semiconductor region having a first conductivity type, an active region formed on the first semiconductor region and configured to generate light using recombination of electrons and holes, and a second semiconductor region formed on the active region and having a second conductivity type, and one side of each of the second ohmic electrode and the light-emitting part is etched to expose the first ohmic electrode to the outside.

According to the present invention, the above object is achieved by a chip die for a semiconductor light-emitting device, including a support substrate, a bonding layer formed on the support substrate, a first ohmic electrode formed on the epitaxial protection layer, a light-emitting part formed on the first ohmic electrode and configured to generate light, and a second ohmic electrode formed on the light-emitting part, wherein the light-emitting part includes a second semiconductor region having a second conductivity type, an active region formed on the second semiconductor region and configured to generate light using recombination of electrons and holes, and a first semiconductor region formed on the active region and having a first conductivity type, and one side of each of the second ohmic electrode and the light-emitting part is etched to expose the first ohmic electrode to the outside.

According to the present invention, the above object is achieved by a method of manufacturing a chip die for a semiconductor light-emitting device, including a light-emitting part forming operation of forming a light-emitting part, which generates light, on a growth substrate, a first electrode forming operation of forming a first ohmic electrode on the light-emitting part, a protection layer forming operation of forming an epitaxial protection layer on the first ohmic electrode, a bonding operation of bonding a support substrate and the epitaxial protection layer through a bonding layer, a removal operation of removing the growth substrate, an etching operation of etching one side of the light-emitting part to expose the first ohmic electrode to the outside, and a second electrode forming operation of forming a second ohmic electrode on the etched light-emitting part, wherein the light-emitting part includes a first semiconductor region having a first conductivity type, an active region formed on the first semiconductor region and configured to generate light using recombination of electrons and holes, and a second semiconductor region formed on the active region and having a second conductivity type.

According to the present invention, the above object is achieved by a method of manufacturing a chip die for a semiconductor light-emitting device, including a light-emitting part forming operation of forming a light-emitting part, which generates light, on a growth substrate, a protection layer forming operation of forming an epitaxial protection layer on the light-emitting part, an adhesion operation of bonding a temporary substrate and the epitaxial protection layer through an adhesive layer, a first removal operation of removing the growth substrate, a first electrode forming operation of forming a first ohmic electrode on a surface of the light-emitting part from which the growth substrate is removed, a bonding operation of bonding a support substrate and the first ohmic electrode through a bonding layer, a second removal operation of removing the temporary substrate, and etching and removing the adhesive layer and the epitaxial protection layer, an etching operation of etching one side of the light-emitting part to expose the first ohmic electrode to the outside, and a second electrode forming operation of forming a second ohmic electrode on the etched light-emitting part, wherein the light-emitting part includes a second semiconductor region having a second conductivity type, an active region formed on the second semiconductor region and configured to generate light using recombination of electrons and holes, and a first semiconductor region formed on the active region and having a first conductivity type.

### Advantageous Effects

According to the present invention, it is possible to simultaneously achieve both the advantage of a mini light-emitting diode (LED) manufacturing process, such as ease of defect classification, and low process and facility investment costs due to the use of existing general-purpose transfer equipment as is, and the advantage of a micro LED manufacturing process, such as a dramatic reduction in thickness and a reduction in chip die size by removing a final support substrate made of sapphire, thereby improving light output.

In addition, according to the present invention, unlike conventional chip dies, in which two electrodes, i.e., a positive electrode and a negative electrode, are exposed to the outside, an epitaxial die of the present invention has a structure in which only one electrode is exposed to the outside, and thus, although electrical sorting through an electro luminescence (EL) measurement method is not possible, the epitaxial die can be optically sorted through high-speed photo luminescence (PL) measurement method, thereby enabling defects (No Good, NG) to be easily identified initially using only optical characteristics (such as wavelength, full-width at half maximum (FWHM), and intensity).

In addition, an epitaxial die of the present invention has the advantage that a process of forming a p-ohmic contact electrode or an n-ohmic contact electrode, which requires high-temperature heat treatment of 300° C. or higher, is completed at the operation of manufacturing the epitaxial die, so that the epitaxial die of the present invention does not require a high-temperature heat treatment process after transfer.

In addition, an epitaxial die of the present invention is attached to a final support substrate made of sapphire, which can be removed after transfer onto a targeted wafer, thereby enabling the die to be repositioned collectively or unitarily (selectively) through conventional chip die transfer processes such as pick & place and replace.

Meanwhile, the effects of the present invention are not limited to the above-mentioned effects, and various effects may be included within the scope which is apparent to those skilled in the art from contents to be described below.

### DESCRIPTION OF DRAWINGS

FIG. 1 illustrates an overall view of an epitaxial die for a semiconductor light-emitting device according to a first embodiment of the present invention.

FIG. 2 is a flowchart of a method of manufacturing the epitaxial die for a semiconductor light-emitting device according to the first embodiment of the present invention.

FIG. 3 illustrates a process of manufacturing the epitaxial die for a semiconductor light-emitting device according to the first embodiment of the present invention.

FIG. 4 illustrates an overall view of an epitaxial die for a semiconductor light-emitting device according to a second embodiment of the present invention.

FIG. 5 is a flowchart of a method of manufacturing the epitaxial die for a semiconductor light-emitting device according to the second embodiment of the present invention.

FIG. 6 illustrates a process of manufacturing the epitaxial die for a semiconductor light-emitting device according to the second embodiment of the present invention.

FIG. 7 illustrates an overall view of a chip die for a semiconductor light-emitting device according to a third embodiment of the present invention.

FIG. 8 is a flowchart of a method of manufacturing the chip die for a semiconductor light-emitting device according to the third embodiment of the present invention.

FIG. 9 illustrates a process of manufacturing the chip die for a semiconductor light-emitting device according to the third embodiment of the present invention.

FIG. 10 illustrates a process of transferring the chip die for a semiconductor light-emitting device according to the third embodiment of the present invention to a substrate part.

FIG. 11 illustrates an overall view of an epitaxial die for a semiconductor light-emitting device according to a fourth embodiment of the present invention.

FIG. 12 is a flowchart of a method of manufacturing the epitaxial die for a semiconductor light-emitting device according to the fourth embodiment of the present invention.

FIG. 13 illustrates a process of manufacturing the epitaxial die for a semiconductor light-emitting device according to the fourth embodiment of the present invention.

FIG. 14 illustrates an overall view of an epitaxial die for a semiconductor light-emitting device according to a fifth embodiment of the present invention.

FIG. 15 is a flowchart of a method of manufacturing the epitaxial die for a semiconductor light-emitting device according to the fifth embodiment of the present invention.

FIG. 16 illustrates a process of manufacturing the epitaxial die for a semiconductor light-emitting device according to the fifth embodiment of the present invention.

FIG. 17 illustrates an overall view of a chip die for a semiconductor light-emitting device according to a sixth embodiment of the present invention.

FIG. 18 is a flowchart of a method of manufacturing the chip die for a semiconductor light-emitting device according to the sixth embodiment of the present invention.

FIG. 19 illustrates a process of manufacturing the chip die for a semiconductor light-emitting device according to the sixth embodiment of the present invention.

FIG. 20 illustrates a process of transferring the chip die for a semiconductor light-emitting device according to the sixth embodiment of the present invention to a substrate part.

### MODES OF THE INVENTION

Hereinafter, some embodiments of the present invention will be described in detail with reference to exemplary drawings. It should be noted that in adding reference numerals to the components of each drawing, the same components have the same number when possible, even though the same components are shown in different drawings

In addition, in describing the embodiments of the present invention, when detailed descriptions of related known structures or functions may obscure the gist of the present invention, the detailed description thereof will be omitted.

In addition, terms such as first, second, A, B, (a), (b), and the like may be used herein to describe components of the embodiments of the present invention. Each of these terms is not used to define an essence, order, or sequence of a corresponding component but used merely to distinguish the corresponding component from other component(s).

The present invention relates to an epitaxial die and a chip die for a semiconductor light-emitting device that emits blue light, green light, or red light. In the present invention, a semi-finished light source die with a size less than or equal to that of a mini light-emitting diode (LED), which can be sorted and has the following characteristics, is defined as the epitaxial die of the present invention.

First, unlike conventional chip dies in which two electrodes, i.e., a positive electrode and a negative electrode, are all exposed to the outside, the epitaxial die of the present invention has a structure in which no electrodes are exposed or only one electrode is exposed to the outside. Accordingly, the epitaxial die of the present invention is not electrically sorted by an electro luminescence (EL) measurement method, but can be optically sorted by a high-speed photo luminescence (PL) measurement method, so that defects (NG) can detected initially using only optical characteristics (wavelength, full width half maximum (FWHM), intensity, and the like).

Second, in the epitaxial die of the present invention, a process of forming a p-ohmic contact electrode or an n-ohmic contact electrode, which requires a high-temperature heat treatment of 300° C. or higher, is completed at the operation of manufacturing the epitaxial die. Accordingly, the epitaxial die of the present invention has the advantage of not requiring a high-temperature heat treatment process after transfer to a substrate part.

Third, the epitaxial die of the present invention includes a sapphire final support substrate attached thereto, which is removed after transfer. Accordingly, the epitaxial die of the present invention has the advantage of being repositionable collectively or per unit (selectively), through typical chip die transfer processes such as pick & place and replace.

That is, the epitaxial die of the present invention and a chip die manufactured therefrom can simultaneously satisfy both the advantage of a mini light-emitting diode (LED) manufacturing process, such as ease of defect classification, and low process and facility investment costs due to the use of existing general-purpose transfer equipment as is, and the advantage of a micro LED manufacturing process, such as a dramatic reduction in thickness and a reduction in chip die size by removing a final support substrate, thereby improving light output.

Hereinafter, with reference to the accompanying drawings, an epitaxial die 100 for a semiconductor light-emitting device according to a first embodiment of the present invention will be described in detail.

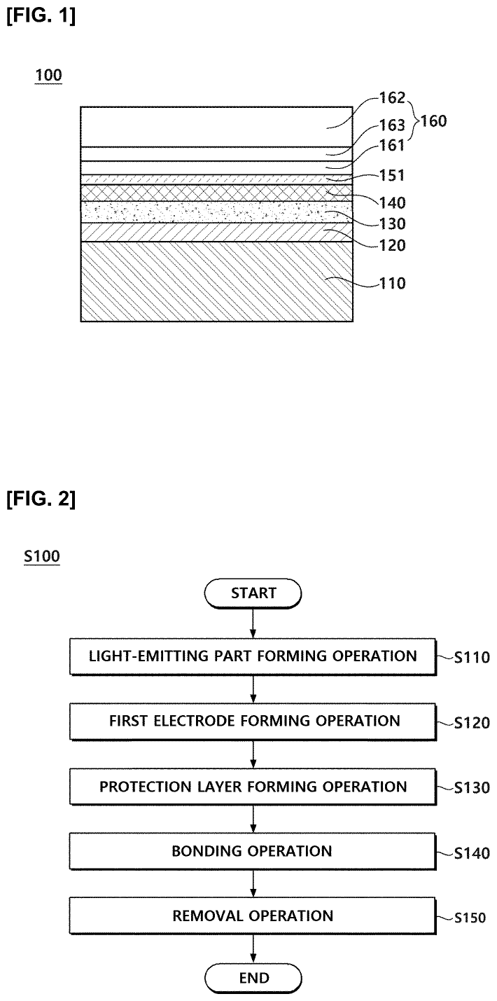

FIG. 1 illustrates an overall view of the epitaxial die for a semiconductor light-emitting device according to the first embodiment of the present invention.

As shown in FIG. 1, an epitaxial die 100 for a semiconductor light-emitting device according to the first embodiment of the present invention includes a support substrate 110, a sacrificial separation layer 120, a bonding layer 130, an epitaxial protection layer 140, a first ohmic electrode 151, and a light-emitting part 160.

The support substrate 110 supports the sacrificial separation layer 120, the bonding layer 130, the epitaxial protection layer 140, the first ohmic electrode 151, and the light-emitting part 160, and when the support substrate 110 is removed through a laser lift-off (LLO) technique after the epitaxial die of the present invention is transferred to a substrate part 10, the support substrate 110 is preferably formed of an optically transparent and high-temperature resistant substrate made of a material that theoretically transmits 100% of a laser beam (single-wavelength light) without absorption, such as sapphire (α-phase Al₂O₃), ScMgAlO4, 4H-SiC, or 6H-SiC.

The sacrificial separation layer 120 is a layer that is sacrificed and removed to separate the support substrate 110 from the bonding layer 130 using a laser beam in the LLO technique, and is formed by being directly grown or formed on the support substrate 110.

That is, the sacrificial separation layer 120 may be composed of oxides and/or nitrides capable of being sacrificially separated by a thermal-chemical decomposition reaction due to the laser beam. The sacrificial separation layer 120 may be formed using physical vapor deposition (PVD) techniques such as sputtering, pulsed laser deposition (PLD), or evaporators, and may also be directly grown on the support substrate 110 through chemical vapor deposition (CVD), and specific examples of materials thereof may include ITO, GaN, InGaN, AlGaN, InAlN, GaOx, GaON, ZnO, InGaZnO, InZnO, or InGaO.

The bonding layer 130 may be formed of a dielectric material that does not undergo physical property changes at temperatures above 1000° C. and in a reducing atmosphere, and has excellent thermal conductivity. For example, the bonding layer 130 may include SiO2, SiNx, SiCN, AlN, and Al2O3, and furthermore, may also include flowable oxides (FOx) such as spin-on glass (SOG, liquid SiO2) or hydrogen silsesquioxane (HSQ) to improve surface roughness.

Meanwhile, a reinforcing layer that enhances bonding strength and induces compressive stress may be formed on at least one of an upper surface and a lower surface of the bonding layer 130.

The reinforcing layer is a layer that enhances the bonding strength with the support substrate 110 and induces compressive stress, and more specifically, the reinforcing layer includes a bonding reinforcing layer and a compressive stress layer.

The compressive stress layer is a layer that induces compressive stress and is formed on at least one of the upper surface and the lower surface of the bonding layer 130. The compressive stress layer includes dielectric materials with a coefficient of thermal expansion greater than that of the support substrate 110, i.e., AlN (4.6 ppm), AlNO (4.6-6.8 ppm), Al2O3 (6.8 ppm), SiC (4.8 ppm), SiCN (3.8-4.8 ppm), GaN (5.6 ppm), and GaNO (5.6-6.8 ppm), which serve to relieve tensile stress, i.e., induce compressive stress, which in turn plays a role in improving product quality by controlling stress.

The bonding reinforcing layer is a layer introduced to enhance bonding strength when the epitaxial protection layer 140 is bonded to the sacrificial separation layer 120 of the support substrate 110 through the bonding layer 130, and is formed on the compressive stress layer. It is preferable that the materials constituting the bonding reinforcing layer are preferentially selected from SiO2, SiNx, and the like.

Meanwhile, in the present invention, the bonding reinforcing layer or the compressive stress layer may be omitted in some cases, and in some cases, the entire reinforcing layer may be omitted, thereby allowing the epitaxial protection layer 140 to come into direct contact with the bonding layer 130, or the sacrificial separation layer 120 to come into direct contact with the bonding layer 130. In such a case, the bonding layer 130 may be a structure formed by depositing a material with a coefficient of thermal expansion greater than that of the support substrate 110, thereby providing bonding functionality while also inducing compressive stress.

The epitaxial protection layer 140 is a layer that prevents the light-emitting part 160 and the first ohmic electrode 151 from being damaged during the process, and may include materials selected in consideration of selective wet etching, such as oxides including SiO2 or the like and nitrides including SiNx or the like, and may also include metals and alloys.

The first ohmic electrode 151 is formed on the epitaxial protection layer 140, and is electrically connected to a first semiconductor region 161, which will be described below, through a p-ohmic contact. The first ohmic electrode 151 may be formed of materials that inherently have high transparency and/or reflectance and excellent electrical conductivity, but the present invention is not limited thereto. The materials of the first ohmic electrode 151 may include optically transparent materials such as indium tin oxide (ITO), zinc oxide (ZnO), indium zinc oxide (IZO), indium gallium zinc oxide (IGZO), and titanium nitride (TiN), and optically reflective materials such as Ag, Al, Rh, Pt, Ni, Pd, Ru, Cu, and Au, and may be used alone, or a combination of the above-described optically transparent materials and optically reflective materials may be used.

At this time, since the first semiconductor region 161 and the first ohmic electrode 151 typically have a surface roughness of less than 1 nm, there is no need for a planarization process such as chemical-mechanical polishing (CMP). However, in some cases, the surface of the first semiconductor region 161 with gallium polarity may be polished and smoothly planarized through CMP, and the surface of the first ohmic electrode 151 may also be polished and smoothly planarized through mechanical polishing (MP) or CMP, and this improvement in surface roughness may result in enhanced bonding strength and improved quality of each layer.

The light-emitting part 160 generates light and can emit blue light, green light, or red light. In the present invention, when the light-emitting part 160 emits blue light or green light, binary, ternary, and quaternary compounds such as InN, InGaN, GaN, AlGaN, AlN, and AlGaInN, which are Group III (Al, Ga, and In) nitride semiconductors among the Group III-V compound semiconductors, may be epitaxially grown on an initial growth substrate G wafer by being arranged at appropriate positions and sequence.

In particular, in order to emit blue light or green light, a high-quality InGaN Group III nitride semiconductor with a high In composition should be preferentially formed on top of Group III nitride semiconductors composed of GaN, AlGaN, AlN, and AlGaInN, but the present invention is not limited thereto.

Further, in the present invention, when the light-emitting part 160 emits red light, binary, ternary, and quaternary compounds such as InP, InGaP, GaP, AlInP, AlGaP, AlP, and AlGaInP, which are Group III (Al, Ga, and In) phosphide semiconductors among Group III-V compound semiconductors, may be epitaxially grown on the initial growth wafer by being arranged at appropriate positions and sequence. In addition, to further improve the value of display panel products and the recent development of equipment and process technology, when emitting red light, a high-quality InGaN group III nitride semiconductor with a high In composition of 30% or more may be preferentially formed on top of Group III nitride semiconductors composed of GaN, AlGaN, AlN, and AlGaInN, in addition to group III phosphide semiconductors.

In particular, in order to emit red light, a high-quality InGaP Group III phosphide semiconductor with a high In composition should be preferentially formed on top of Group III phosphide semiconductors composed of GaP, AlInP, AlGaP, AlP, and AlGaInP, but the present invention is not limited thereto, and for convenience of description, the following description will be based on Group III nitride semiconductors.

More specifically, the light-emitting part 160 includes the first semiconductor region 161 (e.g., a p-type semiconductor region), an active region 163 (e.g., multi-quantum wells (MQWs)), and a second semiconductor region 162 (e.g., an n-type semiconductor region), and the second semiconductor region 162, the active region 163, and the first semiconductor region 161 are sequentially epitaxially grown on the initial growth substrate G, and ultimately, the light-emitting part 160, which includes multiple layers of Group III nitrides, may have an overall thickness typically ranging from about 5.0 to 8.0 μm, but the present invention is not limited thereto.

Each of the first semiconductor region 161, the active region 163, and the second semiconductor region 162 may be formed as either a single layer or multiple layers, and although not shown in the drawing, additional layers, such as a buffer layer and other necessary layers, may be added before epitaxially growing the light-emitting part 160 on the initial growth substrate G to ensure the high quality of the epitaxially grown light-emitting part 160. For example, the buffer layer may typically have a thickness of about 3.5 μm, including a compliant layer (CL) composed of a nucleation layer (NL) and an un-doped semiconductor region to relieve stress and improve thin-film quality. Further, when the growth substrate G is removed using an LLO technique, the sacrificial separation layer 120 may be further provided between the nucleation layer and the un-doped semiconductor region, and a seed layer may function as the sacrificial separation layer 120.

Meanwhile, the epitaxial die of the present embodiment has an n-side up structure in which the second semiconductor region 162 with a second conductivity type (n-type) is arranged at the top, and the first semiconductor region 161 with a first conductivity type is arranged at the bottom.

The first semiconductor region 161 has a first conductivity type (p-type) and is formed on the first ohmic electrode 151. The first semiconductor region 161 may be formed as multiple layers with a thickness ranging from several tens of nanometers (nm) to several micrometers (μm).

The active region 163 generates light by using the recombination of electrons and holes and is formed on the first semiconductor region 161. The active region 163 may be formed as multiple layers with a thickness of several tens of nanometers (nm).

The second semiconductor region 162 has a second conductivity type (n-type) and is formed on the active region 163. The second semiconductor region 162 may have a thickness ranging from 2.0 to 3.5 μm, and an exposed top surface thereof has nitrogen polarity.

That is, the active region 163 is interposed between the first semiconductor region 161 and the second semiconductor region 162, and light is generated when holes in the first semiconductor region 161, which is a p-type semiconductor region, and electrons in the second semiconductor region 162, which is an n-type semiconductor region, recombine in the active region 163.

Accordingly, in the epitaxial die 100 for a semiconductor light-emitting device according to the first embodiment of the present invention, the support substrate 110, the sacrificial separation layer 120, the bonding layer 130, the epitaxial protection layer 140, the first ohmic electrode 151, the first semiconductor region 161, the active region 163, and the second semiconductor region 162 are sequentially stacked to form an n-side up structure in which the metal polarity surface is arranged at the bottom, the nitrogen polarity surface is arranged at the top, and a structure in which the first ohmic electrode 151 is not exposed to the outside.

Hereinafter, with reference to the accompanying drawings, a method (S100) of manufacturing the epitaxial die for a semiconductor light-emitting device according to the first embodiment of the present invention will be described in detail.

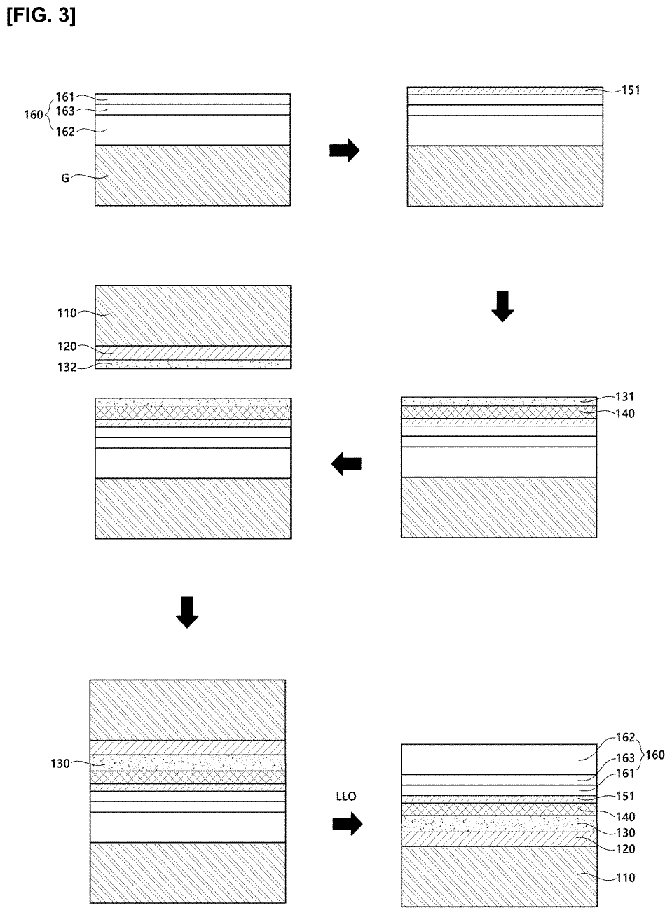

FIG. 2 is a flowchart of the method of manufacturing the epitaxial die for a semiconductor light-emitting device according to the first embodiment of the present invention, and FIG. 3 illustrates a process of manufacturing the epitaxial die for a semiconductor light-emitting device according to the first embodiment of the present invention.

As shown in FIGS. 2 and 3, the method (S100) of manufacturing the epitaxial die for a semiconductor light-emitting device according to the first embodiment of the present invention includes a light-emitting part forming operation S110, a first electrode forming operation S120, a protection layer forming operation S130, a bonding operation S140, and a removal operation S150.

Here, contents of a support substrate 110, a sacrificial separation layer 120, a bonding layer 130, an epitaxial protection layer 140, a first ohmic electrode 151, and a light-emitting part 160, which are not provided in the following description, are the same as those of the epitaxial die 100 for a semiconductor light-emitting device according to the first embodiment of the present invention described above, and thus redundant descriptions will be omitted.

The light-emitting part forming operation S110 is an operation of forming the light-emitting part 160, which generates light, on a growth substrate G.

Here, the light-emitting part 160 includes a first semiconductor region 161 (e.g., a p-type semiconductor region), an active region 163 (e.g., MQWs), and a second semiconductor region 162 (e.g., an n-type semiconductor region), and the second semiconductor region 162, the active region 163, and the first semiconductor region 161 are sequentially epitaxially grown on the initial growth substrate G.

At this time, since the first semiconductor region 161 typically has a surface roughness of less than 1 nm, there is no need for a planarization process such as CMP, but, in some cases, the surface of the first semiconductor region 161 with gallium polarity may be polished and smoothly planarized through CMP to improve the bonding strength and quality of the corresponding layer.

The first electrode forming operation S120 is an operation of forming the first ohmic electrode 151 on the light-emitting part 160.

More specifically, the first ohmic electrode 151 is electrically connected to the first semiconductor region 161 of the light-emitting part 160 through a p-ohmic contact, and may be formed of a material that inherently has high transparency and/or reflectance and excellent electrical conductivity, but the present invention is not limited thereto.

In this case, the first ohmic electrode 151 formed on the surface of the first semiconductor region 161 with gallium polarity typically has a smooth surface, and thus, further polishing or planarization processes are not required, but, in some cases, the surface of the first ohmic electrode 151 may also be polished and smoothly planarized through MP or CMP, and this improvement in surface roughness may result in enhanced bonding strength and improved quality of the corresponding layer.

The protection layer forming operation S130 is an operation of forming the epitaxial protection layer 140 on the first ohmic electrode 151.

The epitaxial protection layer 140 is a layer that prevents the light-emitting part 160 and the first ohmic electrode 151 from being damaged during the process, and may include materials selected in consideration of selective wet etching.

The bonding operation S140 is an operation of bonding the support substrate 110 and the epitaxial protection layer 140 through the bonding layer 130. At this time, in the bonding operation S140, the sacrificial separation layer 120 and the epitaxial protection layer 140 may be bonded through the bonding layer 130 after forming the sacrificial separation layer 120 on the support substrate 110.

In conventional methods, differences in lattice constant (LC) and coefficient of thermal expansion (CTE) between the support substrate 110 and the Group III nitride semiconductor result in significant thermo-mechanical induced stress, leading to substantial bowing of the epitaxial wafer. However, in the present invention, this issue can be resolved by strongly bonding the support substrate 110, which is identical to the growth substrate G, to an upper surface of a Group III nitride semiconductor through the bonding layer 130. That is, in the case of the epitaxial wafer bonded to the support substrate 110, wafer bowing can be minimized to almost zero (0) in a stress-relieved state.

More specifically, in the bonding operation S140, a first bonding layer 131 may be formed on the epitaxial protection layer 140, a second bonding layer 132 may be formed on the sacrificial separation layer 120 of the support substrate 110, and then the first bonding layer 131 and the second bonding layer 132 may be pressed together at a low temperature from room temperature to 300° C. or lower to form the bonding layer 130.

Meanwhile, in the bonding operation S140, a reinforcing layer and the first bonding layer 131 are sequentially stacked and formed on the epitaxial protection layer 140, a reinforcing layer and the second bonding layer 132 are sequentially stacked and formed on the sacrificial separation layer 120 of the support substrate 110, and then the first bonding layer 131 and the second bonding layer 132 are pressed together to form the bonding layer 130.

Here, the reinforcing layer is a layer that enhances the bonding strength with the support substrate 110 and induces compressive stress, and more specifically, the reinforcing layer includes a bonding reinforcing layer and a compressive stress layer.

Meanwhile, in the present invention, the bonding reinforcing layer or the compressive stress layer may be omitted in some cases, and in some cases, the entire reinforcing layer may be omitted, thereby allowing the epitaxial protection layer 140 to come into direct contact with the bonding layer 130, or the sacrificial separation layer 120 to come into direct contact with the bonding layer 130. In such a case, the bonding layer 130 may be a structure formed by depositing a material with a coefficient of thermal expansion greater than that of the support substrate 110, thereby providing bonding functionality while also inducing compressive stress.

The removal operation S150 is an operation of removing the growth substrate G using an LLO technique to expose the surface of the second semiconductor region 162, and cleaning the corresponding exposed surface. When the growth substrate G is removed, the interior of the light-emitting part 160, which has been transferred to the support substrate 110, is in a completely stress-relieved state and maintains a flat condition together with the support substrate 110. Afterward, it is preferable that damaged regions, contaminated surface residues, low-quality single-crystal thin film regions, and the like resulting from the separation of the growth substrate G are removed as completely as possible.

In the epitaxial die manufactured according to the method (S100) of manufacturing the epitaxial die for a semiconductor light-emitting device according to the first embodiment of the present invention as described above, the support substrate 110, the sacrificial separation layer 120, the bonding layer 130, the epitaxial protection layer 140, the first ohmic electrode 151, the first semiconductor region 161, the active region 163, and the second semiconductor region 162 are sequentially stacked to form an n-side up structure in which the metal polarity surface is arranged at the bottom and the nitrogen polarity surface is arranged at the top, and a structure in which the first ohmic electrode 151 is not exposed to the outside.

Hereinafter, with reference to the accompanying drawings, an epitaxial die 200 for a semiconductor light-emitting device according to a second embodiment of the present invention will be described in detail.

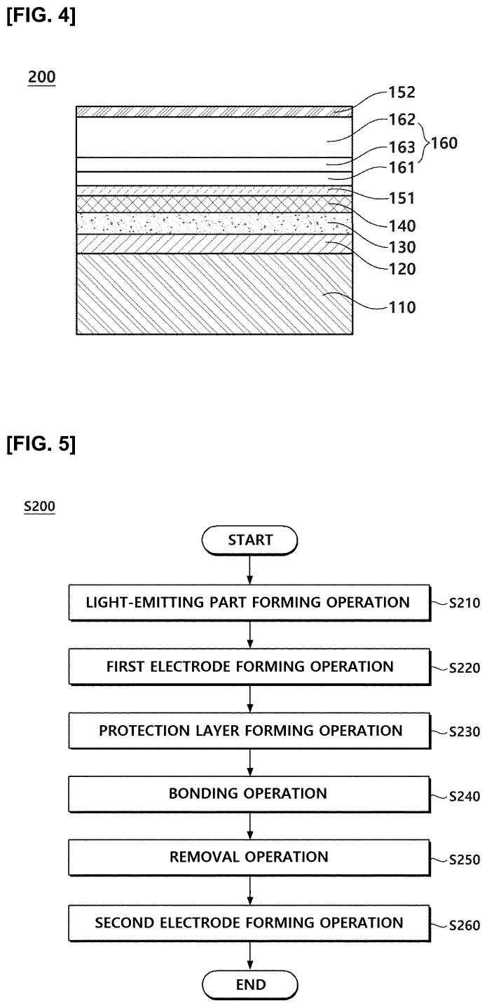

FIG. 4 illustrates an overall view of the epitaxial die for a semiconductor light-emitting device according to the second embodiment of the present invention.

As shown in FIG. 4, the epitaxial die 200 for a semiconductor light-emitting device according to a second embodiment of the present invention includes a support substrate 110, a sacrificial separation layer 120, a bonding layer 130, an epitaxial protection layer 140, a first ohmic electrode 151, a light-emitting part 160, and a second ohmic electrode 152.

Here, contents of the support substrate 110, the sacrificial separation layer 120, the bonding layer 130, the epitaxial protection layer 140, the first ohmic electrode 151, and the light-emitting part 160, which are not provided in the following description, are the same as those of the epitaxial die 100 for a semiconductor light-emitting device according to the first embodiment of the present invention described above, and thus redundant descriptions will be omitted.

The second ohmic electrode 152 is formed on the second semiconductor region 162, and is electrically connected to the second semiconductor region 162 through an n-ohmic contact. The second ohmic electrode 152 may be formed of materials that inherently have high transparency and/or reflectance and excellent electrical conductivity, but the present invention is not limited thereto. The materials of the second ohmic electrode 152 may include optically transparent materials such as indium tin oxide (ITO), zinc oxide (ZnO), indium zinc oxide (IZO), indium gallium zinc oxide (IGZO), and titanium nitride (TiN), and optically reflective materials such as Cr, Ti, Al, V, W, Re, Ag, Cu, and Au, and may be used alone, or a combination of the above-described optically transparent materials and optically reflective materials may be used.

At this time, the second ohmic electrode 152 generally has a smooth surface and does not require a separate polishing or planarization processes, but in some cases, the surface of the second ohmic electrode 152 may also be polished and smoothly planarized through MP or CMP, and this improvement in surface roughness may result in enhanced bonding strength and improved quality of the corresponding layer.

Accordingly, in the epitaxial die 200 for a semiconductor light-emitting device according to the second embodiment of the present invention, the support substrate 110, the sacrificial separation layer 120, the bonding layer 130, the epitaxial protection layer 140, the first ohmic electrode 151, the first semiconductor region 161, the active region 163, the second semiconductor region 162, and the second ohmic electrode 152 are sequentially stacked to form an n-side up structure in which the metal polarity surface is arranged at the bottom, the nitrogen polarity surface is arranged at the top, and a structure in which the first ohmic electrode 151 is not exposed to the outside and only the second ohmic electrode 152 is exposed to the outside.

Hereinafter, with reference to the accompanying drawings, a method (S200) of manufacturing the epitaxial die for a semiconductor light-emitting device according to the second embodiment of the present invention will be described in detail.

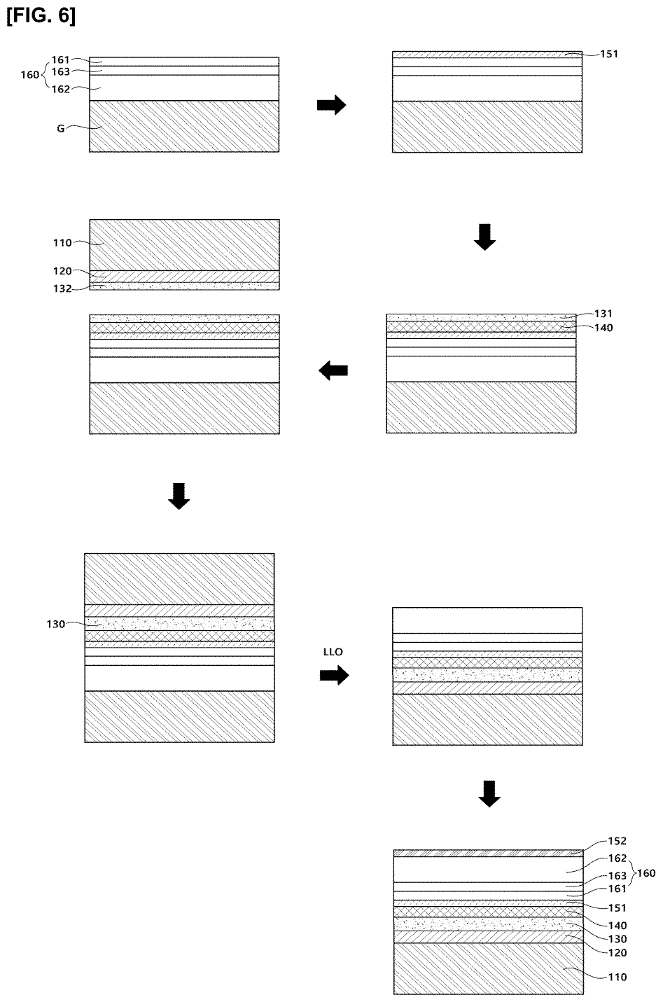

FIG. 5 is a flowchart of the method of manufacturing the epitaxial die for a semiconductor light-emitting device according to the second embodiment of the present invention, and FIG. 6 illustrates a process of manufacturing the epitaxial die for a semiconductor light-emitting device according to the second embodiment of the present invention.

As shown in FIGS. 5 and 6, the method (S200) of manufacturing the epitaxial die for a semiconductor light-emitting device according to the second embodiment of the present invention includes a light-emitting part forming operation S210, a first electrode forming operation S220, a protection layer forming operation S230, a bonding operation S240, a removal operation S250, and a second electrode forming operation S260.

Here, contents of the light-emitting part forming operation S210, the first electrode forming operation S220, the protection layer forming operation S230, the bonding operation S240, and the removal operation S250, which are not provided in the following description, are the same as those in the method (S100) of manufacturing the epitaxial die for a semiconductor light-emitting device according to the first embodiment of the present invention described above, and thus redundant descriptions will be omitted.

The second electrode forming operation S260 is an operation of forming a second ohmic electrode 152 on a surface of a second semiconductor region 162 exposed by removing a growth substrate G.

The second ohmic electrode 152 is formed on the second semiconductor region 162, and is electrically connected to the second semiconductor region 162 through an n-ohmic contact. The second ohmic electrode 152 may be formed of materials that inherently have high transparency and/or reflectance and excellent electrical conductivity, but the present invention is not limited thereto.

At this time, the second ohmic electrode 152 generally has a smooth surface and does not require a separate polishing or planarization processes, but in some cases, the surface of the second ohmic electrode 152 may also be polished and smoothly planarized through MP or CMP, and this improvement in surface roughness may result in enhanced bonding strength and improved quality of the corresponding layer.

In the epitaxial die 200 manufactured according to the method (S200) of manufacturing the epitaxial die for a semiconductor light-emitting device according to the second embodiment of the present invention as described above, a support substrate 110, a sacrificial separation layer 120, a bonding layer 130, an epitaxial protection layer 140, a first ohmic electrode 151, a first semiconductor region 161, an active region 163, the second semiconductor region 162, and the second ohmic electrode 152 are sequentially stacked to form an n-side up structure in which the metal polarity surface is arranged at the bottom and the nitrogen polarity surface is arranged at the top, and a structure in which the first ohmic electrode 151 is not exposed to the outside and only the second ohmic electrode 152 is exposed to the outside.

Hereinafter, with reference to the accompanying drawings, a chip die 300 for a semiconductor light-emitting device according to a third embodiment of the present invention will be described in detail.

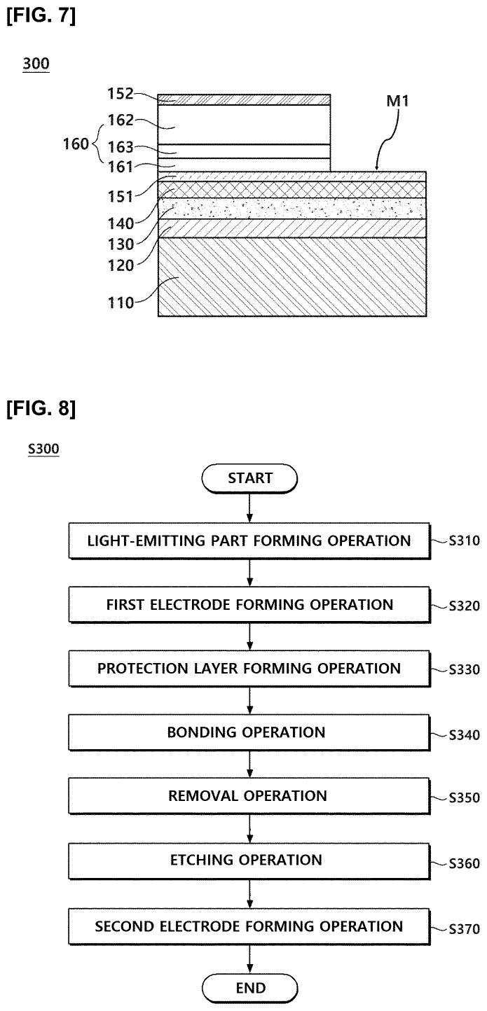

FIG. 7 illustrates an overall view of the chip die for a semiconductor light-emitting device according to the third embodiment of the present invention.

As shown in FIG. 7, the chip die 300 for a semiconductor light-emitting device according to the third embodiment of the present invention includes a support substrate 110, a sacrificial separation layer 120, a bonding layer 130, an epitaxial protection layer 140, a first ohmic electrode 151, a light-emitting part 160, and a second ohmic electrode 152.

Here, contents of the support substrate 110, the sacrificial separation layer 120, the bonding layer 130, the epitaxial protection layer 140, the first ohmic electrode 151, and the light-emitting part 160, which are not provided in the following description, are the same as those of the epitaxial die 100 for a semiconductor light-emitting device according to the first embodiment of the present invention described above, and thus redundant descriptions will be omitted.

The light-emitting part 160 generates light and includes a first semiconductor region 161 (e.g., a p-type semiconductor region), an active region 163 (e.g., MQWs), and a second semiconductor region 162 (e.g., an n-type semiconductor region), and the chip die in the present embodiment has an n-side up structure, in which the second semiconductor region 162 with a second conductivity type (n-type) is arranged at the top and the first semiconductor region 161 with a first conductivity type (p-type) is arranged at the bottom.

At this time, the light-emitting part 160 may be mesa-etched at one side so that a portion of the first ohmic electrode 151 therebelow is exposed to the outside. That is, a mesa-etched region M1 may be formed on one side of the light-emitting part 160.

The second ohmic electrode 152 is formed on the second semiconductor region 162 of the light-emitting part 160, which has been mesa-etched at one side, and is electrically connected to the second semiconductor region 162 through an n-ohmic contact. The second ohmic electrode 152 may be formed of materials that inherently have high transparency and/or reflectance and excellent electrical conductivity, but the present invention is not limited thereto.

At this time, the second ohmic electrode 152 generally has a smooth surface and does not require a separate polishing or planarization processes, but in some cases, the surface of the second ohmic electrode 152 may also be polished and smoothly planarized through MP or CMP, and this improvement in surface roughness may result in enhanced bonding strength and improved quality of each layer.

Accordingly, in the chip die 300 for a semiconductor light-emitting device according to the third embodiment of the present invention, the support substrate 110, the sacrificial separation layer 120, the bonding layer 130, the epitaxial protection layer 140, the first ohmic electrode 151, the first semiconductor region 161, the active region 163, the second semiconductor region 162, and the second ohmic electrode 152 are sequentially stacked to form an n-side up structure in which the metal polarity surface is arranged at the bottom, the nitrogen polarity surface is arranged at the top, and a structure in which the first ohmic electrode 151 and the second ohmic electrode 152 are both exposed to the outside.

Hereinafter, with reference to the accompanying drawings, a method (S300) of manufacturing the chip die for a semiconductor light-emitting device according to the third embodiment of the present invention will be described in detail.

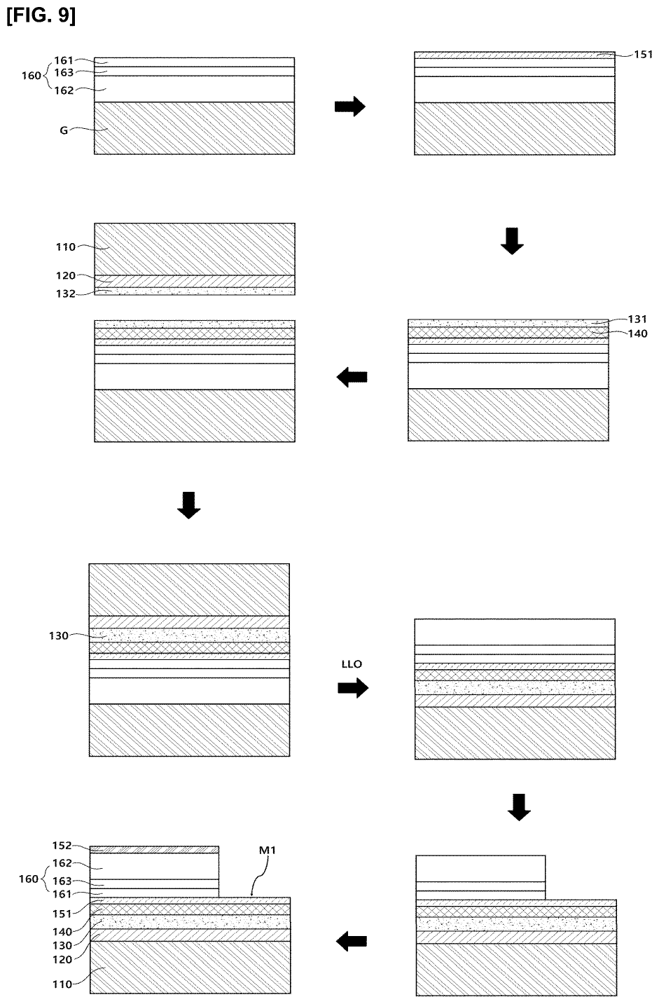

FIG. 8 is a flowchart of a method of manufacturing the chip die for a semiconductor light-emitting device according to the third embodiment of the present invention, and FIG. 9 illustrates a process of manufacturing the chip die for a semiconductor light-emitting device according to the third embodiment of the present invention.

As shown in FIGS. 8 and 9, the method (S300) of manufacturing the chip die for a semiconductor light-emitting device according to the third embodiment of the present invention includes a light-emitting part forming operation S310, a first electrode forming operation S320, a protection layer forming operation S330, a bonding operation S340, a removal operation S350, an etching operation S360, and a second electrode forming operation S370.

Here, contents of the light-emitting part forming operation S310, the first electrode forming operation S320, the protection layer forming operation S330, the bonding operation S340, and the removal operation S350 are the same as those in the method (S100) of manufacturing the epitaxial die for a semiconductor light-emitting device according to the first embodiment of the present invention described above, and thus redundant descriptions will be omitted.

The etching operation S360 is an operation of mesa-etching one side of a light-emitting part 160 from which a growth substrate G has been removed, and exposing a portion of a first ohmic electrode 151 below the light-emitting part 160 to the outside.

The second electrode forming operation S370 is an operation of forming a second ohmic electrode 152 on a second semiconductor region 162 of the light-emitting part 160, which has been mesa-etched at one side, and here, the second ohmic electrode 152 is electrically connected to the second semiconductor region 162 through an n-ohmic contact.

The second ohmic electrode 152 may be formed of materials that inherently have high transparency and/or reflectance and excellent electrical conductivity, but the present invention is not limited thereto.

At this time, the second ohmic electrode 152 generally has a smooth surface and does not require a separate polishing or planarization processes, but in some cases, the surface of the second ohmic electrode 152 may also be polished and smoothly planarized through MP or CMP, and this improvement in surface roughness may result in enhanced bonding strength and improved quality of each layer.

In the chip die manufactured according to the method (S300) of manufacturing the chip die for a semiconductor light-emitting device according to the third embodiment of the present invention as described above, a support substrate 110, a sacrificial separation layer 120, a bonding layer 130, an epitaxial protection layer 140, the first ohmic electrode 151, a first semiconductor region 161, an active region 163, the second semiconductor region 162, and the second ohmic electrode 152 are sequentially stacked to form an n-side up structure in which the metal polarity surface is arranged at the bottom and the nitrogen polarity surface is arranged at the top, and a structure in which the first ohmic electrode 151 and the second ohmic electrode 152 are both exposed to the outside.

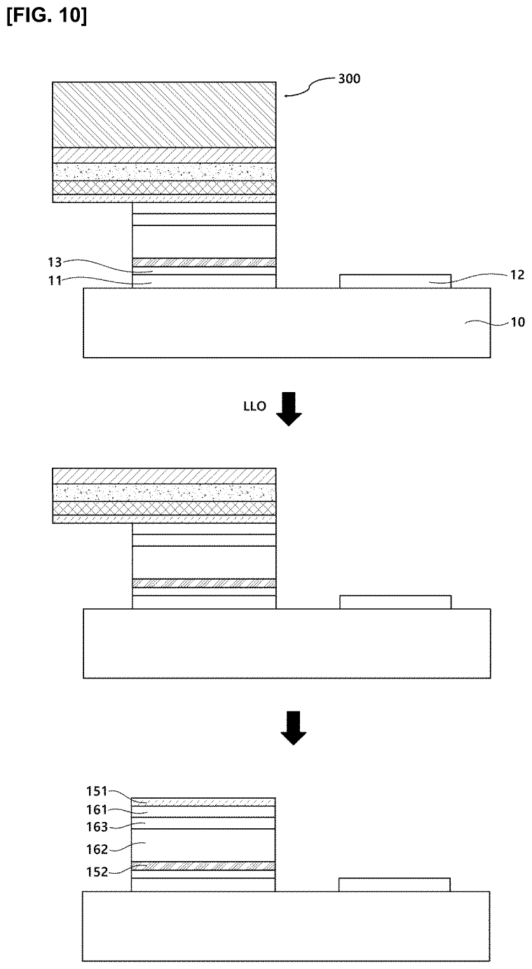

Meanwhile, FIG. 10 illustrates a process of transferring the chip die for a semiconductor light-emitting device according to the third embodiment of the present invention to a substrate part.

As shown in FIG. 10, a substrate part 10 includes a first electrode pad 11, which is a common electrode, and a second electrode pad 12, which is an individual electrode, each formed on an upper surface thereof, and since the chip die (or epitaxial die) of the present invention includes the support substrate 110, the second ohmic electrode 152, which is an n-ohmic electrode, can be easily bonded to the first electrode pad 11, which is a negative electrode, through a bonding layer 13 using typical chip die transfer processes such as pick & place and replace. Subsequently, the sacrificial separation layer 120, the bonding layer 130, and the epitaxial protection layer 140 are etched and removed after removing the support substrate 110 using an LLO technique, and then the second ohmic electrode 152 is etched to the size of a pixel light source, which allows a distance between display pixels, i.e., a pitch, to be reduced, thereby realizing a high-resolution panel.

Hereinafter, with reference to the accompanying drawings, an epitaxial die 400 for a semiconductor light-emitting device according to a fourth embodiment of the present invention will be described in detail.

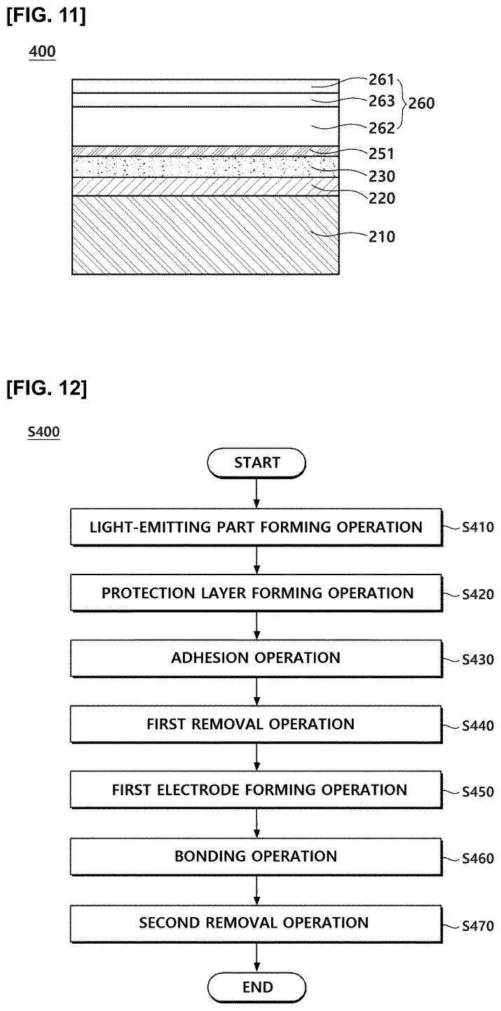

FIG. 11 illustrates an overall view of the epitaxial die for a semiconductor light-emitting device according to the fourth embodiment of the present invention.

As shown in FIG. 11, the epitaxial die 400 for a semiconductor light-emitting device according to the fourth embodiment of the present invention includes a support substrate 210, a sacrificial separation layer 220, a bonding layer 230, a first ohmic electrode 251, and a light-emitting part 260.

Here, contents of the support substrate 210, the sacrificial separation layer 220, the bonding layer 230, the first ohmic electrode 251, and the light-emitting part 260, which are not provided in the following description, are the same as those of the epitaxial die 100 for a semiconductor light-emitting device according to the first embodiment of the present invention described above, and thus redundant descriptions will be omitted.

The support substrate 210 supports the sacrificial separation layer 220, the bonding layer 230, the first ohmic electrode 251, and the light-emitting part 260, and when the support substrate 210 is removed through an LLO technique after the epitaxial die of the present invention is transferred to a substrate part 20, the support substrate 210 is preferably formed of an optically transparent and high-temperature resistant substrate made of a material that theoretically transmits 100% of a laser beam (single-wavelength light) without absorption, i.e., sapphire (α-phase Al2O3), ScMgAlO4, 4H-SiC, or 6H-SiC.

The sacrificial separation layer 220 is a layer that is sacrificed and removed to separate the support substrate 210 from the bonding layer 230 using a laser beam in the LLO technique, and is formed by being directly grown or formed on the support substrate 210.

The bonding layer 230 may be formed of a dielectric material that does not undergo physical property changes at temperatures above 1000° C. and in a reducing atmosphere, and has excellent thermal conductivity. For example, the bonding layer 230 may include SiO2, SiNx, SiCN, AlN, and Al2O3, and furthermore, may also include flowable oxides (FOx) such as spin-on glass (SOG, liquid SiO2) or hydrogen silsesquioxane (HSQ) to improve surface roughness.

Meanwhile, a reinforcing layer that enhances bonding strength and induces compressive stress may be formed on at least one of an upper surface and a lower surface of the bonding layer 230.

The reinforcing layer is a layer that enhances the bonding strength with the support substrate 210 and induces compressive stress, and more specifically, the reinforcing layer includes a bonding reinforcing layer and a compressive stress layer.

Meanwhile, in the present invention, the bonding reinforcing layer or the compressive stress layer may be omitted in some cases, and in some cases, the entire reinforcing layer may be omitted, thereby allowing the epitaxial protection layer 240 to come into direct contact with the bonding layer 230, or the sacrificial separation layer 220 to come into direct contact with the bonding layer 230. In such a case, the bonding layer 230 may be a structure formed by depositing a material with a coefficient of thermal expansion greater than that of the support substrate 210, thereby providing bonding functionality while also inducing compressive stress.

The first ohmic electrode 251 is formed on the bonding layer 230, and is electrically connected to a second semiconductor region 262, which will be described below, through an n-ohmic contact. The first ohmic electrode 251 may be formed of materials that inherently have high transparency and/or reflectance and excellent electrical conductivity, but the present invention is not limited thereto. The materials of the first ohmic electrode 251 may include optically transparent materials such as indium tin oxide (ITO), zinc oxide (ZnO), indium zinc oxide (IZO), indium gallium zinc oxide (IGZO), and titanium nitride (TiN), and optically reflective materials such as Cr, Ti, Al, V, W, Re, and Au, and may be used alone, or a combination of the above-described optically transparent materials and optically reflective materials may be used.

At this time, the second semiconductor region 262 and the first ohmic electrode 251 generally have smooth surfaces and do not require a separate polishing or planarization processes, but in some cases, the surface of the second semiconductor region 262 with nitrogen polarity may be polished and smoothly planarized through CMP, and the surface of the first ohmic electrode 251 may also be polished and smoothly planarized through MP or CMP, this improvement in surface roughness may result in enhanced bonding strength and improved quality of each layer.

The light-emitting part 260 generates light and includes a first semiconductor region 261 (e.g., a p-type semiconductor region), an active region 263 (e.g., MQWs), and the second semiconductor region 262 (e.g., an n-type semiconductor region), and the epitaxial die in the present embodiment has a p-side up structure, in which the first semiconductor region 261 with a first conductivity type (p-type) is arranged at the top and second semiconductor region 262 with a second conductivity type (n-type) is arranged at the bottom.

The second semiconductor region 262 has a second conductivity type (n-type) and is formed on the first ohmic electrode 251. The second semiconductor region 262 may have a thickness of 2.0 to 3.5 μm.

The active region 263 generates light by using the recombination of electrons and holes and is formed on the second semiconductor region 262. The active region 263 may be formed as multiple layers with a thickness of several tens of nanometers (nm).

The first semiconductor region 261 has a first conductivity type (p-type), and is formed on the active region 263. The first semiconductor region 261 may be formed as multiple layers with a thickness ranging from several tens of nanometers (nm) to several micrometers (μm), and has metal polarity on a top surface thereof.

Accordingly, in the epitaxial die 400 for a semiconductor light-emitting device according to the fourth embodiment of the present invention, the support substrate 210, the sacrificial separation layer 220, the bonding layer 230, the first ohmic electrode 251, the second semiconductor region 262, the active region 263, and the first semiconductor region 261 are sequentially stacked to form a p-side up structure in which the nitrogen polarity surface is arranged at the bottom and the metal polarity surface is arranged at the top, and a structure in which the first ohmic electrode 251 is not exposed to the outside.

Hereinafter, with reference to the accompanying drawings, a method (S400) of manufacturing the epitaxial die for a semiconductor light-emitting device according to the fourth embodiment of the present invention will be described in detail.

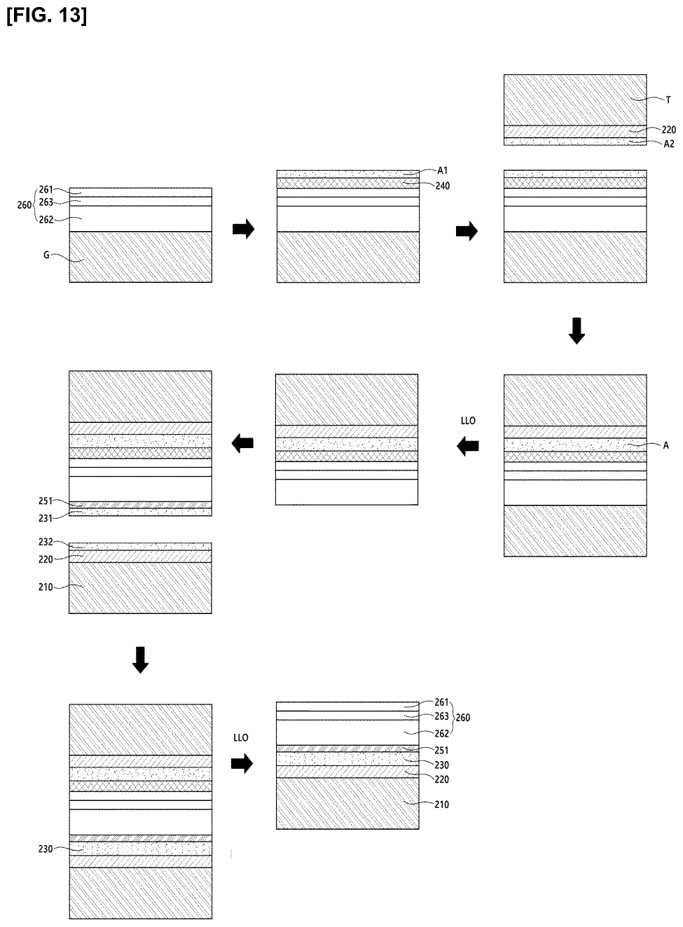

FIG. 12 is a flowchart of the method of manufacturing the epitaxial die for a semiconductor light-emitting device according to the fourth embodiment of the present invention, and FIG. 13 illustrates a process of manufacturing the epitaxial die for a semiconductor light-emitting device according to the fourth embodiment of the present invention.

As shown in FIGS. 12 and 13, the method (S400) of manufacturing the epitaxial die for a semiconductor light-emitting device according to the fourth embodiment of the present invention includes a light-emitting part forming operation S410, a protection layer forming operation S420, an adhesion operation S430, a first removal operation S440, a first electrode forming operation S450, a bonding operation S460, and a second removal operation S470.

Here, contents of a support substrate 210, a sacrificial separation layer 220, a bonding layer 230, a first ohmic electrode 251, and a light-emitting part 260, which are not provided in the following description, are the same as those of the epitaxial die 400 for a semiconductor light-emitting device according to the fourth embodiment of the present invention described above, and thus redundant descriptions will be omitted.

The light-emitting part forming operation S410 is an operation of forming the light-emitting part 260, which generates light, on a growth substrate G.

Here, the light-emitting part 260 includes a first semiconductor region 261 (e.g., a p-type semiconductor region), an active region 263 (e.g., MQWs), and a second semiconductor region 262 (e.g., an n-type semiconductor region), and the second semiconductor region 262, the active region 263, and the first semiconductor region 261 are sequentially epitaxially grown on the initial growth substrate G.

At this time, since the surface of the first semiconductor region 261 with gallium polarity typically has a surface roughness of 1 nm or less, planarization processes such as CMP or the like are not required, but in some cases, the surface may be further polished and smoothly planarized through CMP, resulting in enhanced bonding strength and improved quality of the corresponding layer.

The protection layer forming operation S420 is an operation of forming an epitaxial protection layer 240 on the first semiconductor region 261.

The epitaxial protection layer 240 is a layer that prevents the light-emitting part 260 from being damaged during the process, and may include materials selected in consideration of selective wet etching.

The adhesion operation S430 is an operation of bonding a temporary substrate T and the epitaxial protection layer 240 through an adhesive layer A. At this time, in the adhesion operation S430, the sacrificial separation layer 220 and the epitaxial protection layer 240 may be bonded through the adhesive layer A after forming the sacrificial separation layer 220 on the temporary substrate T.

More specifically, in the adhesion operation S430, a first adhesive layer A1 may be formed on the epitaxial protection layer 240, a second adhesive layer A2 may be formed on the sacrificial separation layer 220 of the temporary substrate T, and then the first adhesive layer A1 and the second adhesive layer A2 may be pressed together to form the adhesive layer A.

The first removal operation S440 is an operation of removing the growth substrate G using an LLO technique to expose the surface of the second semiconductor region 262, and cleaning the corresponding exposed surface. When the growth substrate G is removed, the interior of the light-emitting part 260, which has been transferred to the temporary substrate T, is in a completely stress-relieved state and maintains a flat condition together with the temporary substrate T. Afterward, it is preferable that damaged regions, contaminated surface residues, low-quality single-crystal thin film regions, and the like resulting from the separation of the growth substrate G are removed as completely as possible.

The first electrode forming operation S450 is an operation of forming the first ohmic electrode 251 on the surface of the second semiconductor region 262 exposed by removing the growth substrate G.

More specifically, the first ohmic electrode 251 is electrically connected to the second semiconductor region 262 through an n-ohmic contact, and may be formed of a material that inherently has high transparency and/or reflectance and excellent electrical conductivity, but the present invention is not limited thereto.

At this time, the first ohmic electrode 251 generally has a smooth surface and does not require a separate polishing or planarization processes, but in some cases, the surface of the first ohmic electrode 251 may also be polished and smoothly planarized through MP or CMP, and this improvement in surface roughness may result in enhanced bonding strength and improved quality of the corresponding layer.

The bonding operation S460 is an operation of bonding the support substrate 210 and the first ohmic electrode 251 through the bonding layer 230. At this time, in the bonding operation S460, the sacrificial separation layer 220 and the first ohmic electrode 251 may be bonded through the bonding layer 230 after forming the sacrificial separation layer 220 on the support substrate 210.

In conventional methods, differences in lattice constant (LC) and coefficient of thermal expansion (CTE) between the support substrate 210 and a Group III nitride semiconductor result in significant thermo-mechanical induced stress, leading to substantial bowing of the epitaxial wafer. However, in the present invention, this issue can be resolved by strongly bonding the temporary substrate T, which is identical to the growth substrate G, to an upper surface of the group III nitride semiconductor through the bonding layer 230, and then bonding the support substrate 210, which is identical to the growth substrate G, to a lower surface of the group III nitride semiconductor. That is, in the case of the epitaxial wafer bonded to the support substrate 210, wafer bowing can be minimized to almost zero (0) in a stress-relieved state.

More specifically, in the bonding operation S460, a first bonding layer 231 may be formed on the first ohmic electrode 251, a second bonding layer 232 may be formed on the sacrificial separation layer 220 of the support substrate 210, and then the first bonding layer 231 and the second bonding layer 232 may be pressed together at a low temperature from room temperature to 300° C. or lower to form the bonding layer 230.

Meanwhile, in the bonding operation S460, a reinforcing layer and the first bonding layer 231 are sequentially stacked and formed on the first ohmic electrode 251, a reinforcing layer and the second bonding layer 232 are sequentially stacked and formed on the sacrificial separation layer 220 of the support substrate 210, and then the first bonding layer 231 and the second bonding layer 232 are pressed together to form the bonding layer 230.

Here, the reinforcing layer is a layer that enhances the bonding strength with the support substrate 210 and induces compressive stress, and more specifically, the reinforcing layer includes a bonding reinforcing layer and a compressive stress layer.

Meanwhile, in the present invention, the bonding reinforcing layer or the compressive stress layer may be omitted in some cases, and in some cases, the entire reinforcing layer may be omitted, thereby allowing the epitaxial protection layer 240 to come into direct contact with the bonding layer 230, or the sacrificial separation layer 220 to come into direct contact with the bonding layer 230. In such a case, the bonding layer 230 may be a structure formed by depositing a material with a coefficient of thermal expansion greater than that of the support substrate 210, thereby providing bonding functionality while also inducing compressive stress.

The second removal operation S470 is an operation of removing the temporary substrate T using an LLO technique, and removing the sacrificial separation layer 220, the adhesive layer A, and the epitaxial protection layer 240 to expose the surface of the first semiconductor region 261, and cleaning the corresponding surface. When the temporary substrate T is removed, the interior of the light-emitting part 260, which has been transferred to the support substrate 210, is in a completely stress-relieved state and maintains a flat condition together with the support substrate 210. Afterward, it is preferable that damaged regions, contaminated surface residues, low-quality single-crystal thin film regions, and the like resulting from the separation of the temporary substrate T are removed as completely as possible.

In the epitaxial die manufactured according to the method (S400) of manufacturing the epitaxial die for a semiconductor light-emitting device according to the fourth embodiment of the present invention as described above, the support substrate 210, the sacrificial separation layer 220, the bonding layer 230, the first ohmic electrode 251, the first semiconductor region second semiconductor region 262, the active region 263, and the first semiconductor region 261 are sequentially stacked to form a p-side up structure in which the nitrogen polarity surface is arranged at the bottom and the metal polarity surface is arranged at the top, and a structure in which the first ohmic electrode 251 is not exposed to the outside.

Hereinafter, with reference to the accompanying drawings, an epitaxial die 500 for a semiconductor light-emitting device according to a fifth embodiment of the present invention will be described in detail.

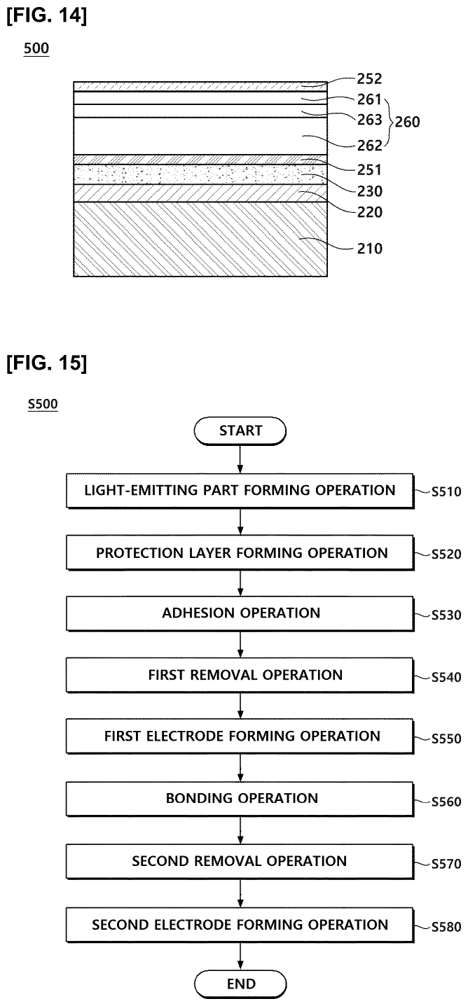

FIG. 14 illustrates an overall view of the epitaxial die for a semiconductor light-emitting device according to the fifth embodiment of the present invention.

As shown in FIG. 14, the epitaxial die 500 for a semiconductor light-emitting device according to the fifth embodiment of the present invention includes a support substrate 210, a sacrificial separation layer 220, a bonding layer 230, a first ohmic electrode 251, a light-emitting part 260, and a second ohmic electrode 252.

Here, contents of the support substrate 210, the sacrificial separation layer 220, the bonding layer 230, the first ohmic electrode 251, and the light-emitting part 260, which are not provided in the following description, are the same as those of the epitaxial die 400 for a semiconductor light-emitting device according to the fourth embodiment of the present invention described above, and thus redundant descriptions will be omitted.

The second ohmic electrode 252 is formed on a first semiconductor region 261, and is electrically connected to the first semiconductor region 261 through a p-ohmic contact. The second ohmic electrode 252 may be formed of materials that inherently have high transparency and/or reflectance and excellent electrical conductivity, but the present invention is not limited thereto. The materials of the second ohmic electrode 252 may include optically transparent materials such as indium tin oxide (ITO), zinc oxide (ZnO), indium zinc oxide (IZO), indium gallium zinc oxide (IGZO), and titanium nitride (TiN), and optically reflective materials such as Ag, Al, Rh, Pt, Ni, Pd, Ru, Cu, and Au, and may be used alone, or a combination of the above-described optically transparent materials and optically reflective materials may be used.

At this time, the second ohmic electrode 252 generally has a smooth surface and does not require a separate polishing or planarization processes, but in some cases, the surface of the second ohmic electrode 252 may also be polished and smoothly planarized through MP or CMP, and this improvement in surface roughness may result in enhanced bonding strength and improved quality of the corresponding layer.

Accordingly, in the epitaxial die 500 for a semiconductor light-emitting device according to the fifth embodiment of the present invention, the support substrate 210, the sacrificial separation layer 220, the bonding layer 230, the first ohmic electrode 251, a second semiconductor region 262, an active region 263, the first semiconductor region 261, and the second ohmic electrode 252 are sequentially stacked to form a p-side up structure in which the nitrogen polarity surface is arranged at the bottom and the metal polarity surface is arranged at the top, and a structure in which the first ohmic electrode 251 is not exposed to the outside and only the second ohmic electrode 252 is exposed to the outside.

Hereinafter, with reference to the accompanying drawings, a method (S500) of manufacturing the epitaxial die for a semiconductor light-emitting device according to the fifth embodiment of the present invention will be described in detail.

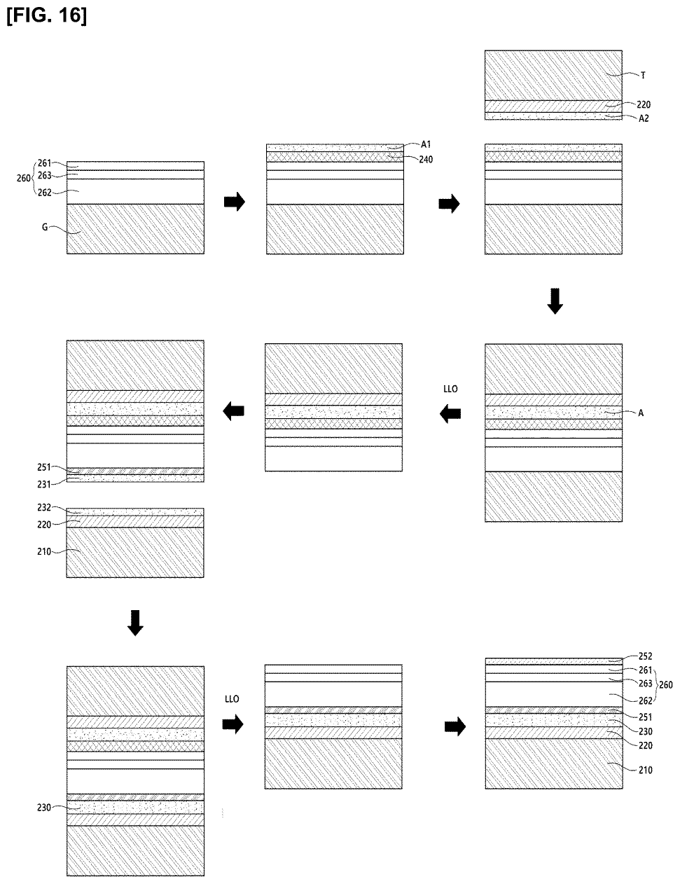

FIG. 15 is a flowchart of the method of manufacturing the epitaxial die for a semiconductor light-emitting device according to the fifth embodiment of the present invention, and FIG. 16 illustrates a process of manufacturing the epitaxial die for a semiconductor light-emitting device according to the fifth embodiment of the present invention.

As shown in FIGS. 15 and 16, the method (S500) of manufacturing the epitaxial die for a semiconductor light-emitting device according to the fifth embodiment of the present invention includes a light-emitting part forming operation S510, a protection layer forming operation S520, an adhesion operation S530, a first removal operation S540, a first electrode forming operation S550, a bonding operation S560, a second removal operation S570, and a second electrode forming operation S580.

Here, contents of the light-emitting part forming operation S510, the protection layer forming operation S520, the adhesion operation S530, the first removal operation S540, the first electrode forming operation S550, the bonding operation S560, and the second removal operation S570, which are not provided in the following description, are the same as those of the method (S400) of manufacturing the epitaxial die for a semiconductor light-emitting device according to the fourth embodiment of the present invention described above, and thus redundant descriptions will be omitted.

The second electrode forming operation S580 is an operation of forming a second ohmic electrode 252 on a surface of a first semiconductor region 261 exposed by removing a temporary substrate T.

The second ohmic electrode 252 is formed on the first semiconductor region 261, and is electrically connected to the first semiconductor region 261 through a p-ohmic contact. The second ohmic electrode 252 may be formed of materials that inherently have high transparency and/or reflectance and excellent electrical conductivity, but the present invention is not limited thereto.

At this time, the second ohmic electrode 252 generally has a smooth surface and does not require a separate polishing or planarization processes, but in some cases, the surface of the second ohmic electrode 252 may also be polished and smoothly planarized through MP or CMP, and this improvement in surface roughness may result in enhanced bonding strength and improved quality of the corresponding layer.

In the epitaxial die manufactured according to the method (S500) of manufacturing the epitaxial die for a semiconductor light-emitting device according to the fifth embodiment of the present invention as described above, a support substrate 210, a sacrificial separation layer 220, a bonding layer 230, a first ohmic electrode 251, a second semiconductor region 262, an active region 263, the first semiconductor region 261, and the second ohmic electrode 252 are sequentially stacked to form a p-side up structure in which the nitrogen polarity surface is arranged at the bottom and the metal polarity surface is arranged at the top, and a structure in which the first ohmic electrode 251 is not exposed to the outside and only the second ohmic electrode 252 is exposed to the outside.

Hereinafter, with reference to the accompanying drawings, a chip die 600 for a semiconductor light-emitting device according to a sixth embodiment of the present invention will be described in detail.

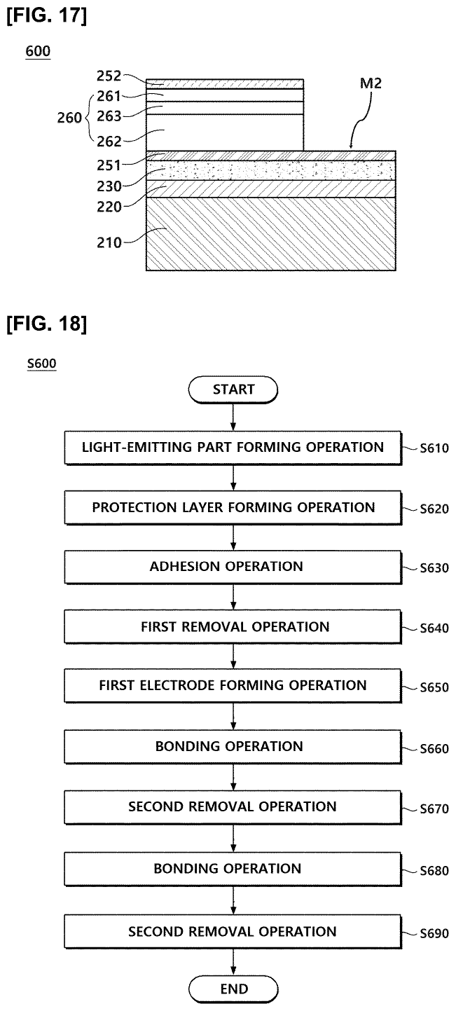

FIG. 17 illustrates an overall view of the chip die for a semiconductor light-emitting device according to the sixth embodiment of the present invention.

As shown in FIG. 17, the chip die 600 for a semiconductor light-emitting device according to the sixth embodiment of the present invention includes a support substrate 210, a sacrificial separation layer 220, a bonding layer 230, a first ohmic electrode 251, a light-emitting part 260, and a second ohmic electrode 252.

Here, contents of the support substrate 210, the sacrificial separation layer 220, the bonding layer 230, the first ohmic electrode 251, and the light-emitting part 260, which are not provided in the following description, are the same as those of the epitaxial die 400 for a semiconductor light-emitting device according to the fourth embodiment of the present invention described above, and thus redundant descriptions will be omitted.

The light-emitting part 260 generates light and includes a first semiconductor region 261 (e.g., a p-type semiconductor region), an active region 263 (e.g., MQWs), and the second semiconductor region 262 (e.g., an n-type semiconductor region), and the chip die in the present embodiment has a p-side up structure, in which the first semiconductor region 261 with a first conductivity type (p-type) is arranged at the top and the second semiconductor region 262 with a second conductivity type (n-type) is arranged at the bottom.

At this time, the light-emitting part 260 may be mesa-etched at one side so that the first ohmic electrode 251 therebelow is exposed to the outside. That is, a mesa-etched region M2 may be formed on one side of the light-emitting part 260.

The second ohmic electrode 252 is formed on the first semiconductor region 261 of the light-emitting part 260, which has been mesa-etched at one side, and is electrically connected to the first semiconductor region 261 through a p-ohmic contact. The second ohmic electrode 252 may be formed of materials that inherently have high transparency and/or reflectance and excellent electrical conductivity, but the present invention is not limited thereto.

At this time, the second ohmic electrode 252 generally has a smooth surface and does not require a separate polishing or planarization processes, but in some cases, the surface of the second ohmic electrode 252 may also be polished and smoothly planarized through MP or CMP, and this improvement in surface roughness may result in enhanced bonding strength and improved quality of each layer.

Accordingly, in the chip die 600 for a semiconductor light-emitting device according to the sixth embodiment of the present invention, the support substrate 210, the sacrificial separation layer 220, the bonding layer 230, the first ohmic electrode 251, the second semiconductor region 262, the active region 263, the first semiconductor region 261, and the second ohmic electrode 252 are sequentially stacked to form a p-side up structure in which the nitrogen polarity surface is arranged at the bottom and the metal polarity surface is arranged at the top, and a structure in which the first ohmic electrode 251 and the second ohmic electrode 252 are both exposed to the outside.

Hereinafter, with reference to the accompanying drawings, a method (S600) of manufacturing the chip die for a semiconductor light-emitting device according to the sixth embodiment of the present invention will be described in detail.

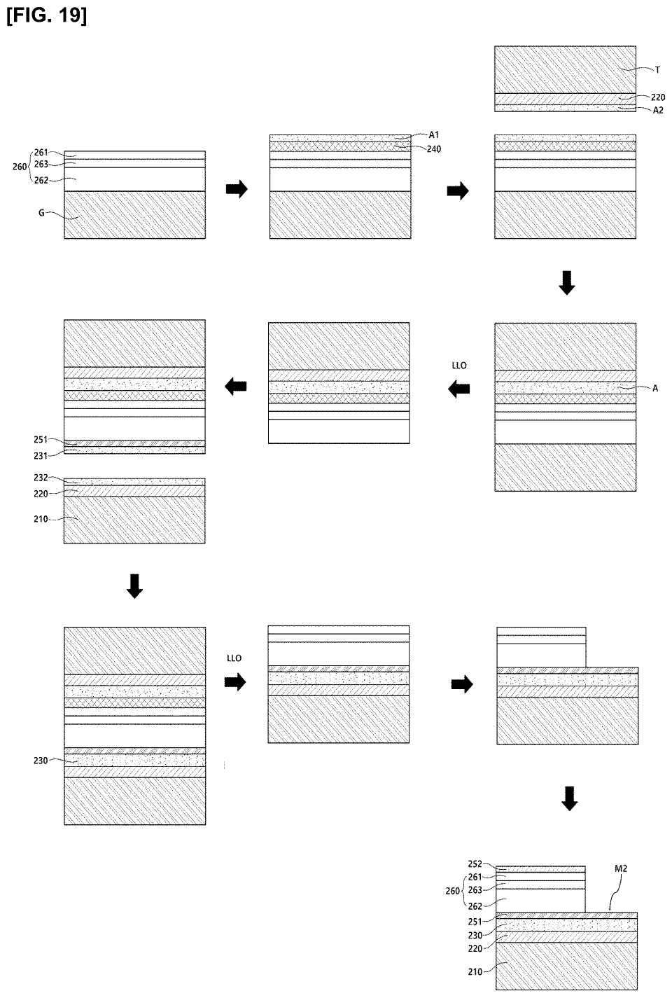

FIG. 18 is a flowchart of the method of manufacturing the chip die for a semiconductor light-emitting device according to the sixth embodiment of the present invention, and FIG. 19 illustrates a process of manufacturing the chip die for a semiconductor light-emitting device according to the sixth embodiment of the present invention.

As shown in FIGS. 18 and 19, the method (S600) of manufacturing the chip die for a semiconductor light-emitting device according to the sixth embodiment of the present invention includes a light-emitting part forming operation S610, a protection layer forming operation S620, an adhesion operation S630, a first removal operation S640, a first electrode forming operation S650, a bonding operation S660, a second removal operation S670, an etching operation S680, and a second electrode forming operation S690.

Here, contents of the light-emitting part forming operation S610, the protection layer forming operation S620, the adhesion operation S630, the first removal operation S640, the first electrode forming operation S650, the bonding operation S660, and the second removal operation S670, which are not provided in the following description, are the same as those of the method (S400) of manufacturing the epitaxial die for a semiconductor light-emitting device according to the fourth embodiment of the present invention described above, and thus redundant descriptions will be omitted.

The etching operation S680 is an operation of mesa-etching one side of a light-emitting part 260 from which a temporary substrate T has been removed, and exposing a portion of a first ohmic electrode 251 below the light-emitting part 260 to the outside.

The second electrode forming operation S690 is an operation of forming a second ohmic electrode 252 on a first semiconductor region 261 of the light-emitting part 260, which has been mesa-etched at one side, and here, the second ohmic electrode 252 is electrically connected to the first semiconductor region 261 through a p-ohmic contact.

The second ohmic electrode 252 may be formed of materials that inherently have high transparency and/or reflectance and excellent electrical conductivity, but the present invention is not limited thereto.

At this time, the second ohmic electrode 252 generally has a smooth surface and does not require a separate polishing or planarization processes, but in some cases, the surface of the second ohmic electrode 252 may also be polished and smoothly planarized through MP or CMP, and this improvement in surface roughness may result in enhanced bonding strength and improved quality of each layer.

In the chip die manufactured according to the method (S600) of manufacturing the chip die for a semiconductor light-emitting device according to the sixth embodiment of the present invention as described above, a support substrate 210, a sacrificial separation layer 220, a bonding layer 230, the first ohmic electrode 251, a second semiconductor region 262, an active region 263, the first semiconductor region 261, and the second ohmic electrode 252 are sequentially stacked to form a p-side up structure in which the nitrogen polarity surface is arranged at the bottom and the metal polarity surface is arranged at the top, and a structure in which the first ohmic electrode 251 and the second ohmic electrode 252 are both exposed to the outside.

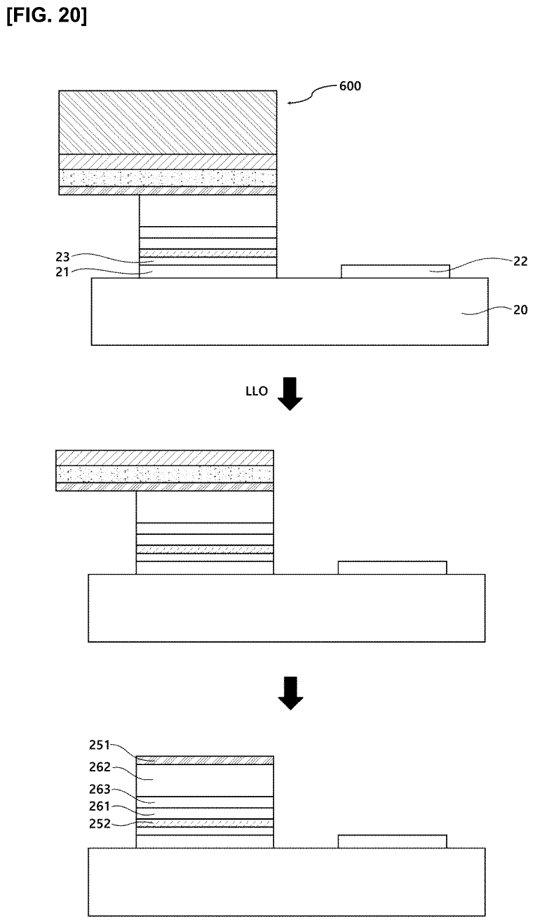

Meanwhile, FIG. 20 illustrates a process of transferring the chip die for a semiconductor light-emitting device according to the sixth embodiment of the present invention to a substrate part.

As shown in FIG. 20, a substrate part 20 includes a first electrode pad 21, which is a common electrode, and a second electrode pad 22, which is an individual electrode, each formed on an upper surface thereof, and since the chip die (or epitaxial die) of the present invention includes the support substrate 210, the second ohmic electrode 252, which is a p-ohmic electrode, can be easily bonded to the first electrode pad 21, which is a positive electrode, through a bonding layer 23 using typical chip die transfer processes such as pick & place and replace. Subsequently, the sacrificial separation layer 220 and the bonding layer 230 are etched and removed after removing the support substrate 210 using an LLO technique, and then the second ohmic electrode 252 is etched to the size of a pixel light source, which allows a distance between display pixels, i.e., a pitch, to be reduced, thereby realizing a high-resolution panel.

Although all the components constituting the embodiments of the present invention have been described as being combined or combined to operate as one, the present invention is not necessarily limited to these embodiments. That is, one or more of all the components may be combined to operate as one without departing from the scope of the purpose of the present invention.

Further, the terms “comprising”, “including”, or “having” may mean that a corresponding component may be present, unless specifically stated otherwise, and it should interpreted as including other components rather than excluding other components. Unless defined otherwise, all terms used herein, including technical or scientific terms, have the same meanings as those generally understood by those skilled in the art to which the present invention pertains. Commonly used terms, such as terms defined in a dictionary, should be interpreted as being consistent with the contextual meaning of the related art and are not interpreted in an ideal or excessively formal meaning unless explicitly defined herein.

The above description is merely illustrative of the technical idea of the present invention, and those skilled in the art to which the present invention pertains may make various modifications and variations without departing from the essential characteristics of the present invention.

Accordingly, the embodiments disclosed in the present invention are not intended to limit the technical idea of the present invention, but are for illustrative purposes, and the scope of the technical idea of the present invention is not limited by these embodiments. The spirit and scope of the present invention should be interpreted by the appended claims and encompass all equivalents falling within the scope of the appended claims.

1. An epitaxial die for a semiconductor light-emitting device, which is formed by separating into die units and functions as a pixel after being individually transferred to a substrate part, comprising:
a support substrate;
a sacrificial separation layer formed on the support substrate, wherein the sacrificial separation layer is sacrificed to separate the support substrate when the epitaxial die is transferred to the substrate part;
a bonding layer formed on the sacrificial separation layer;
an epitaxial protection layer formed on the bonding layer;
a first ohmic electrode formed on the epitaxial protection layer; and
a light-emitting part formed on the first ohmic electrode and configured to generate light,
wherein the light-emitting part includes a first semiconductor region, which is a p-type semiconductor region, an active region formed on the first semiconductor region and configured to generate light using recombination of electrons and holes, and a second semiconductor region formed on the active region and which is a n-type semiconductor region,
wherein the epitaxial protection layer formed of SiO₂ or SINₓ,
wherein the first ohmic electrode is electrically connected to the first semiconductor region through a p-ohmic contact
wherein the first ohmic electrode is interposed between the epitaxial protection layer and the first semiconductor region, and is not exposed to the outside before the epitaxial die is transferred to the substrate part,
wherein the support substrate is optically transparent, and it is possible to determine optical defects of the epitaxial die before the epitaxial die is transferred to the substrate part.

2-3. (canceled)

4. The epitaxial die of claim 1, further comprising a second ohmic electrode formed on the second semiconductor region,
wherein the second ohmic electrode is electrically connected to the second semiconductor region through an n-ohmic contact.

5. An epitaxial die for a semiconductor light-emitting device, which is formed by separating into die units and functions as a pixel after being individually transferred to a substrate part, comprising:
a support substrate;
a sacrificial separation layer formed on the support substrate, wherein the sacrificial separation layer is sacrificed to separate the support substrate when the epitaxial die is transferred to the substrate part;
a bonding layer formed on the sacrificial separation layer;
a first ohmic electrode formed on the bonding layer; and
a light-emitting part formed on the first ohmic electrode and configured to generate light,
wherein the light-emitting part includes a first semiconductor region, which is a n-type semiconductor region, an active region formed on the first semiconductor region and configured to generate light using recombination of electrons and holes, and a second semiconductor region formed on the active region and which is a p-type semiconductor region,
wherein the first ohmic electrode is electrically connected to the second semiconductor region through a n-ohmic contact,
wherein the first ohmic electrode is interposed between the bonding layer and the second semiconductor region, and is not exposed to the outside before the epitaxial die is transferred to the substrate part,
wherein the support substrate is optically transparent, and it is possible to determine optical defects of the epitaxial die before the epitaxial die is transferred to the substrate part.

6-7. (canceled)

8. The epitaxial die of claim 5, further comprising a second ohmic electrode formed on the first semiconductor region,
wherein the second ohmic electrode is electrically connected to the first semiconductor region through a p-ohmic contact.

9-16. (canceled)

17. A chip die for a semiconductor light-emitting device, which is formed by separating into die units and functions as a pixel after being individually transferred to a substrate part, comprising:
a support substrate;
a sacrificial separation layer formed on the support substrate, wherein the sacrificial separation layer is sacrificed to separate the support substrate when the chip die is transferred to the substrate part;
a bonding layer formed on the sacrificial separation layer;
an epitaxial protection layer formed on the bonding layer;
a first ohmic electrode formed on the epitaxial protection layer;
a light-emitting part formed on the first ohmic electrode and configured to generate light; and
a second ohmic electrode formed on the light-emitting part,
wherein the light-emitting part includes a first semiconductor region, which is a p-type semiconductor region, an active region formed on the first semiconductor region and configured to generate light using recombination of electrons and holes, and a second semiconductor region formed on the active region and, which is a n-type semiconductor region,
wherein the epitaxial protection layer formed of SiO₂ or SINₓ,
wherein the first ohmic electrode is electrically connected to the first semiconductor region through a p-ohmic contact,
wherein the second ohmic electrode is electrically connected to the second semiconductor region through a n-ohmic contact,
wherein one side of each of the second ohmic electrode and the light-emitting part is etched to expose the first ohmic electrode to the outside,
wherein the support substrate is optically transparent, and it is possible to determine optical defects of the chip die before the chip die is transferred to the substrate part.

18-28. (canceled)
